(19) United States
(12) Patent Application Publication
(10) Pub. No.: US 2008/0093716 A1
(43) Pub. Date: Apr. 24, 2008

(54) SEMICONDUCTOR DEVICE AND METHOD OF MANUFACTURING SEMICONDUCTOR DEVICE

(75) Inventors: Shirou OKADA, Kanagawa (JP); Ryoichi Shigematsu, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/874,223

(22) Filed: Oct. 18, 2007

(30) Foreign Application Priority Data
Oct. 18, 2006 (JP) 2006-283393

(51) Int. Cl. H01L 21/02; H01L 23/495

(52) U.S. Cl. 257/669; 438/123; 257/E23.043; 257/E21.536

(57) ABSTRACT

A semiconductor device of the present invention includes a lead frame having an island portion having a roughened upper surface and side faces, and an unroughened lower surface, and also having a plurality of leads having roughened inner lead portions and unroughened outer lead portions; a semiconductor chip placed on the upper surface of the island portion of the lead frame; a plurality of electrode pads provided on the upper surface of the semiconductor chip; a plurality of wires connecting the plurality of electrode pads and the plurality of leads; and a resin molding the semiconductor chip.

This application is based on Japanese patent application No. 2006-283393 the content of which is incorporated hereinto by reference.

### BACKGROUND

1. Technical Field

The present invention relates to a semiconductor device and a method of manufacturing a semiconductor device, and in particular to a resin-molded semiconductor device using a lead frame, and a method of manufacturing the same.

2. Related Art

Before describing of the present invention, the related art will be explained in detail with reference to FIGS. 5 and 6 in order to facilitate the understanding of the present invention.

A conventional semiconductor device 7 shown in FIG. 5 contains a lead frame 1, a semiconductor chip 4 placed on an island portion 2 of the lead frame 1 while placing an adhesive 3 in between, a plurality of wires 5 respectively connecting a plurality of electrodes of the semiconductor chip 4 and a plurality of leads of the lead frame 1, and a resin 6 molding the semiconductor chip 4.

The conventional semiconductor device 7 has been suffering from a risk of causing separation over a wide region in the mold, due to lack of an anchor effect. In view of improving adhesiveness between the resin 6 and the lead frame 1, there has been an increasing trend of adopting a technique of roughening the entire surface of the lead frame 1 of a conventional semiconductor device 10 using a roughening plated layer 8, as shown in FIG. 6. Roughening of the entire surface raises the anchor effect, and makes the separation less likely to occur.

A semiconductor device described in Japanese Laid-Open Patent Publication No. 2003-158234 improves adhesiveness between external electrode terminals of a non-lead-type semiconductor device and a molding material, by roughening the entire one surface of the lead frame 1 by plasma cleaning. Alternatively, surfaces of leads and tab-suspension leads of a lead frame are transformed into a patterned indented surface by pressing.

The conventional techniques described in the foregoing documents still remain for further improvement in the aspects shown below.

Roughening of the lead frame 1 extensively up to the outer lead portions thereof, as seen in the in the conventional semiconductor device 10, may degrade solder wettability.

### SUMMARY

In one embodiment, there is provided a semiconductor device which includes a lead frame having an island portion having a roughened upper surface and side faces, and an unroughened lower surface, and a plurality of leads having roughened inner lead portions and unroughened outer lead portions;

a semiconductor chip placed on the upper surface of the island portion of the lead frame;

a plurality of electrode pads provided on the upper surface of the semiconductor chip;

a plurality of wires connecting the plurality of electrode pads and the plurality of leads; and

a resin molding the semiconductor chip.

According to this invention, by roughening the upper surface and the side faces of the island portion, and the inner lead portions of a plurality of leads, the lead frame can ensure a desirable level of adhesiveness with the resin, and can thereby prevent separation-induced cracking at bonded portions of bonding wires, and degradation in reliability caused by infiltrated water. On the other hand, by leaving the lower surface of the island portion unroughened, the lower surface of the island portion can be separated from the resin, so that stress can be relaxed rather than being concentrated on the corners of the island portion, and thereby the cracking may be avoidable. Leaving the outer lead portions of a plurality of leads unroughened also facilitates image recognition of inter-lead alignment under an electron microscope, when the semiconductor device is mounted on a board. Wettability to solder also improves. Moreover, roughening is given only portions later contained inside the mold, so that a nonconformity such as producing resin burr in the process of resin molding is avoidable. A highly reliable semiconductor device may be provided in this way.

While a configuration of the present invention has been described in the above, the present invention includes various embodiments without being limited thereto.

For example, in another embodiment, there is provided a method of manufacturing a semiconductor device which includes obtaining a lead frame having a plurality of leads having inner lead portions and outer lead portions, and an island portion;

masking regions other than the inner lead portions of the plurality of leads, and the upper surface and the side faces of the island portion of the lead frame;

roughening the inner lead portions of the plurality of leads, and the upper surface and the side faces of the island portion;

placing a semiconductor chip on the roughened upper surface of the island portion of the lead frame;

bonding a plurality of electrode pads provided on the upper surface of the semiconductor chip and the roughened inner lead portions of the plurality of leads; and

molding the semiconductor chip using a resin.

According to the present invention, a highly-reliable semiconductor device is successfully prevented from causing cracks and from being degraded in wettability to solder in the process of mounting, while being kept in good adhesiveness between a lead frame and a resin, is provided.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view schematically showing a semiconductor device according to an embodiment of the present invention;

FIGS. 2A and 2B are plan views explaining process steps of masking the semiconductor device shown in FIG. 1;

FIGS. 3A to 3F are sectional views explaining process steps of manufacturing the semiconductor device shown in FIG. 1;

FIG. 4 is a sectional view schematically showing another embodiment of the present invention;

FIG. 5 is a sectional view schematically showing a conventional semiconductor device; and

FIG. 6 is a sectional view schematically showing another conventional semiconductor device.

### DETAILED DESCRIPTION

The invention will now be described herein with reference to illustrative embodiments. Those skilled in the art will recognize that many alternative embodiments can be accomplished using the teachings of the present invention and that the invention is not limited to the embodiment illustrated for explanatory purposes.

Paragraphs below will describe embodiments of the present invention referring to the attached drawings. It is to be understood that any common constituents will be given with similar reference numerals in all drawings, and explanations therefore will not be repeated.

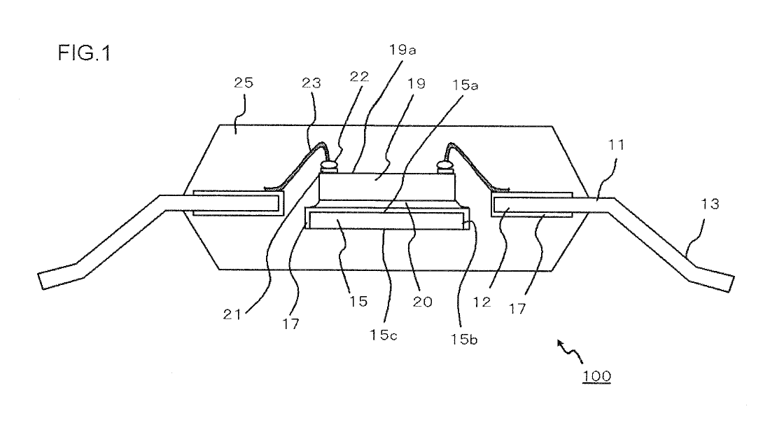

FIG. 1 is a sectional view schematically showing a semiconductor device according to an embodiment of the present invention. A semiconductor device 100 of this embodiment has a lead frame 11 which has an island portion 15 having a roughened upper surface 15a and side faces 15b, and an unroughened lower surface 15c, and a plurality of leads having roughened inner lead portions (inner leads 12) and unroughened outer lead portions (outer leads 13); a semiconductor chip 19 placed on the upper surface 15a of the island portion 15 of the lead frame 11; a plurality of electrode pads 21 provided on the upper surface 19a of the semiconductor chip 19; a plurality of wires 23 connecting the plurality of electrode pads 21 and the plurality of leads (inner leads 12); and a resin 25 molding the semiconductor chip 19.

The drawings shown hereinafter will not show configurations of portions not essential to the present invention.

For details, in the semiconductor device 100 of this embodiment, the lead frame 11 contains the island portion 15, the inner leads 12, and the outer leads 13. The present invention is particularly effective for copper lead frames having a large coefficient of expansion, and palladium-plated lead frames generally poor in adhesiveness with the resin.

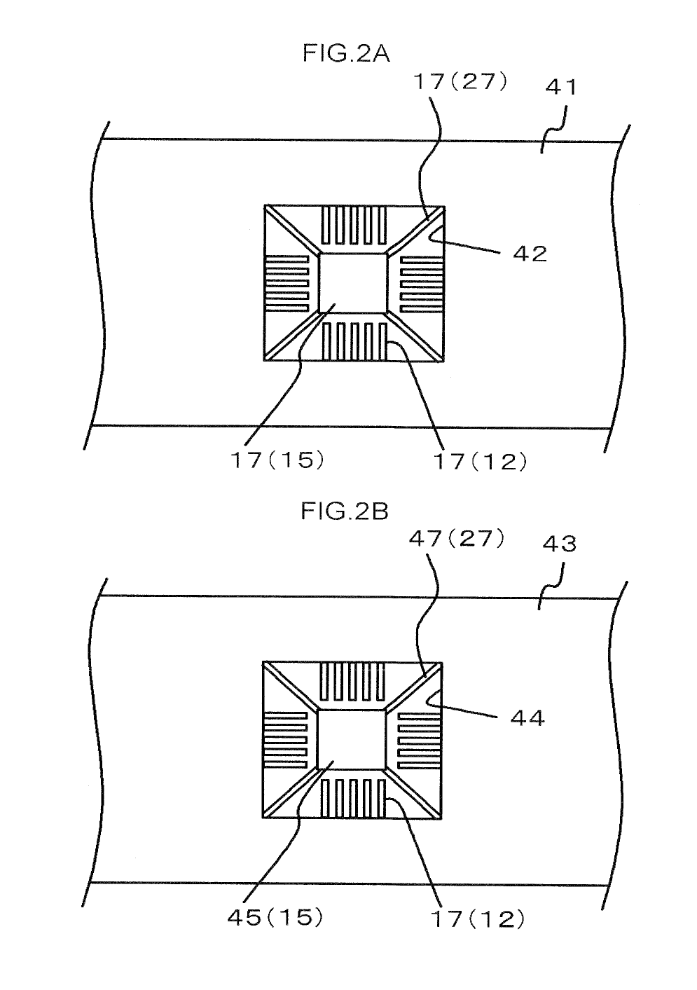

For the case where a plated layer is formed, a masking sheet for upper surface 41 is opposed to the upper surface of the lead frame 11 shown in FIG. 2A, a masking sheet for back surface 43 shown in FIG. 2B is opposed to the back surface of the lead frame 11, the lead frame 11 is held therebetween on both sides thereof, so as to expose only portions to be plated while masking the other portions, and is subjected to plating. The masking sheet for upper surface 41 and the masking sheet for back surface 43 are typically composed of rubber sheets.

As shown in FIG. 2A, the masking sheet for upper surface 41 has a rectangular opening 42 allowing the inner leads 12, the island portion 15 and suspension pins 27 of the lead frame 11 to be exposed therein. On the other hand, as shown in FIG. 2B, masking sheet for back surface 43 has a rectangular opening 44, provided therein with an island portion mask 45 having a geometry capable of masking the island portion 15, and suspension components 47 for holding the island portion mask 45 in the opening 44, so as to allow only the inner leads 12 and the suspension pins 27 of the lead frame 11 to be exposed therein.

The lead frame 11 held, from both sides thereof, between masking sheet for upper surface 41 and the masking sheet for back surface 43 is subjected to reflow process. By this process, a roughening plated layer 17 is formed over the entire surface of the inner leads 12 of the lead frame 11, and also on the upper surface 15a and the side faces 15b of the island portion 15 of the lead frame 11, as shown in FIG. 1. On the other hand, the roughening plated layer 17 is not formed on the masked lower surface 15c of the island portion 15.

The roughening plated layer 17 includes a smooth nickel plated layer firstly formed on the surface of the lead frame 11, a roughening nickel plated layer formed on the smooth plated layer, a palladium layer formed on the roughening plated layer, and a gold plated layer formed on the palladium layer. The plating is conducted by electrolytic plating, wherein conditions for forming the roughening plated layer are preferably such as raising current density, and raising metal density in a plating solution. It is further preferable to increase thickness of the plated layer by extending the plating time, while keeping other plating conditions unchanged.

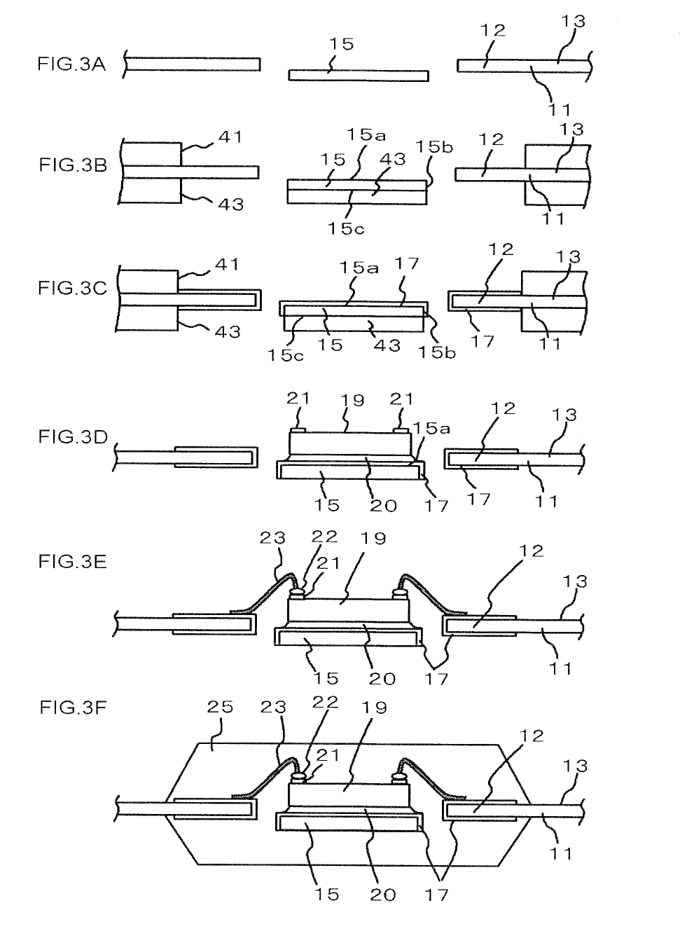

Next, a method of manufacturing the semiconductor device 100 of this embodiment will be explained, referring to FIGS. 3A to 3F. FIG. 3A to FIG. 3F are sectional views showing the individual process steps of manufacturing the semiconductor device 100 of this embodiment.

The method of manufacturing the semiconductor device 100 of this embodiment includes, obtaining a lead frame 11 having a plurality of leads having the inner lead portions (inner leads 12) and the outer lead portions (outer leads 13), and an island portion 15 (FIG. 3A); masking regions other than the inner lead portions (inner leads 12) of the plurality of leads, and the upper surface 15a and the side faces 15b of the island portion 15 of the lead frame 11 (FIG. 3B); roughening the inner lead portions (inner leads 12) of the plurality of leads, and the upper surface 15a and the side faces 15b of the island portion 15 (FIG. 3C); placing a semiconductor chip 19 on the roughened upper surface 15a of the island portion 15 of the lead frame 11 (FIG. 3D); bonding a plurality of electrode pads 21 provided on the upper surface 19a of the semiconductor chip 19 and the roughened inner lead portions (inner leads 12) of the plurality of leads (FIG. 3E); and molding the semiconductor chip 19 using a resin 25 (FIG. 3F).

For details, firstly as shown in FIG. 3A, the lead frame 11 is obtained. In this embodiment, the lead frame 11 is a copper lead frame. The present invention is effective for copper lead frames having a coefficient of expansion, at room temperature up to 300° C., of as large as 16 ppm or more and 22 ppm or less, and preferably approximately 16.5 ppm. The present invention is especially effective also for palladium lead frames generally poor in adhesive to resin 25.

Next, as shown in FIG. 3B, the lead frame 11 is held between the masking sheet for upper surface 41 and the masking sheet for back surface 43, so as to oppose the former with the upper surface of the lead frame 11, and the latter with the back surface. The state up to this time is such that the entire surface of the inner leads 12 of the lead frame 11, and the upper surface 15a and the side faces 15b of the island portion 15 of the lead frame 11 are exposed. This way of masking allows roughening of only portions of the lead frame 11 later contained inside the mold, rather than roughening over the entire surface of the lead frame 11. Area for roughening at this time is determined taking variation in misalignment of molding dies into consideration.

Next, as shown in FIG. 3C, the roughening plated layer 17 is formed over the entire surface of the inner leads 12 of the lead frame 11, and the upper surface 15a and the side faces 15b of the island portion 15 of the lead frame 11. Formation of the roughening plated layer 17 has described in the above. Palladium plating for forming the third layer, and gold plating for forming the fourth layer are carried out, after the masking sheet for upper surface 41 and the masking sheet for back surface 43 are removed, as shown in FIG. 3D.

Ratio of specific surface areas of the unroughened smooth surface (the lower surface 15c of the island portion 15, and the surface of the outer leads 13), to the roughened surface having the roughening plated layer 17 formed thereon (the upper surface 15a and the side faces 15b of the island portion 15, and the surface of the inner leads 12) is 1 (smooth surface):1.25 (roughened surface) or around. Arithmetic Mean Deviation of the Profile (Ra) actually measured was 29.4 nm to 108.9 nm. The ratio of specific surface areas of the roughened surface relative to the unroughened surface is preferably 1.15 or larger. As described in the above, the roughened surface has larger arithmetic mean deviation of the profile as compared with the unroughened surface.

Alternatively, in another embodiment, the nickel plated layer, the palladium plated layer and the gold plated layer may be formed after the lead frame 11 was roughened by etching. By this process, the upper surface 15a and the side faces 15b of the island portion 15 of the lead frame 11, and the surface of the inner leads 12 of the lead frame 11 are roughened.

Next, as shown in FIG. 3D, the masking sheet for upper surface 41 and the masking sheet for back surface 43 are removed, and the semiconductor chip 19 is placed on the upper surface 15a of the island portion 15 of the lead frame 11, while placing an adhesive 20 in between.

Next, as shown in FIG. 3E, a bump 22 is formed on each of a plurality of electrode pads 21 of the semiconductor chip 19, and the electrode pads 21 are bonded by wire bonding using wires 23 such as thin gold wires to the corresponded inner leads 12 of the lead frame 11 through the bumps 22. Next, as shown in FIG. 3F, the resin 25 is formed by molding so as to incorporate therein the semiconductor chip 19, the wires 23, and the island portion 15 and the inner leads 12 of the lead frame 11. Of course the resin 25 used herein may be a general epoxy resin, even a biphenyl-base resin, which is inexpensive but poor in the adhesiveness, may be applicable to the resin 25 in the present invention, while ensuring a desirable level of reliability. Thereafter, the outer leads 13 of the lead frame 11 are shaped according to a predetermined geometry, so as to complete the semiconductor device 100 shown in FIG. 1.

Experimental results of adhesiveness between the resin 25 and the roughened lead frame 11 in thus manufactured semiconductor device 100 showed better adhesiveness as compared with the case of using unroughened lead frame 11. By roughening the upper surface 15a and the side faces 15b of the island portion 15, and the surface of the inner leads 12, these components may be kept well adhesive to the resin 25, and thereby separation-induced cracking at the bonded portions of the bonding wires, and degradation in reliability caused by infiltrated water, can be prevented.

In a conventional semiconductor device shown in FIG. 6, roughening over the entire surface of the lead frame 1 may concentrate stress applied to the semiconductor device 10 onto the corners of the island portion 2, and may cause cracks during temperature cycle test. On the contrary, according to the semiconductor device 100 of this embodiment having the lower surface 15c of the island portion 15 left unroughened, so as to allow the lower surface 15c of the island portion 15 to separate from the resin 25, stress can be relaxed rather than being concentrated on the corners of the island portion, thereby the cracking may be avoidable, and the reliability may be improved.

In the mounting process of the conventional semiconductor device 10 shown in FIG. 6, inter-lead alignment has been proceeded while observing an image of the surface of the semiconductor device 10 under an electron microscope, wherein the entirely roughened semiconductor device 10 has made the image recognition difficult because of degraded image quality. In contrast, the semiconductor device 100 of this embodiment has the outer leads 13 of the lead frame 11 left unroughened, so that the image under an electron microscope can more readily be recognized in the process of inter-lead alignment when the semiconductor device 100 is mounted on the board. Wettability to solder also improves. Roughening of only the portions later contained inside the mold successfully avoids nonconformities such as producing resin burr in the process of resin molding. In addition, an inexpensive general-purpose molding material may be used, making it no more necessary to use expensive special-purpose epoxy resin in order to obtain a desirable level of adhesiveness.

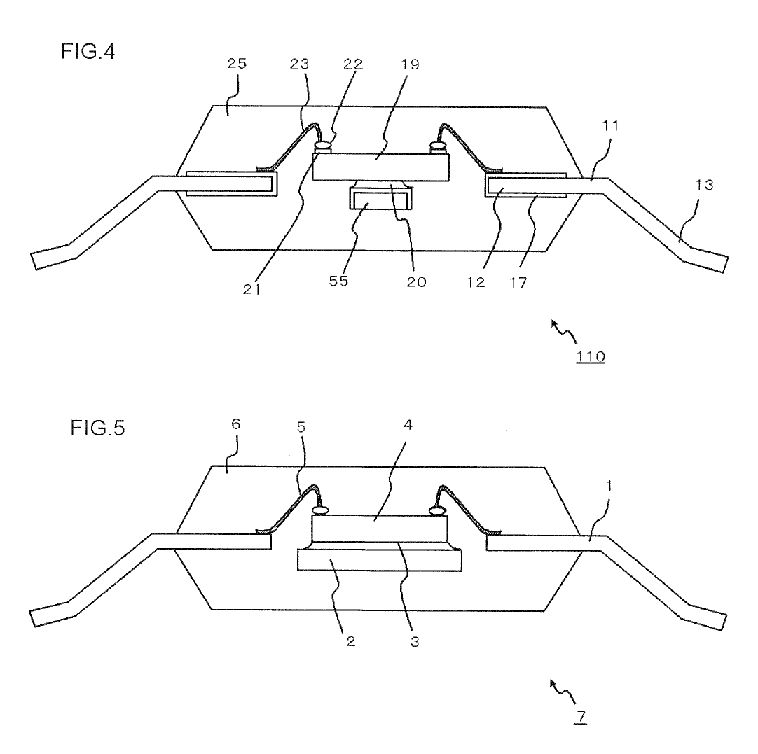

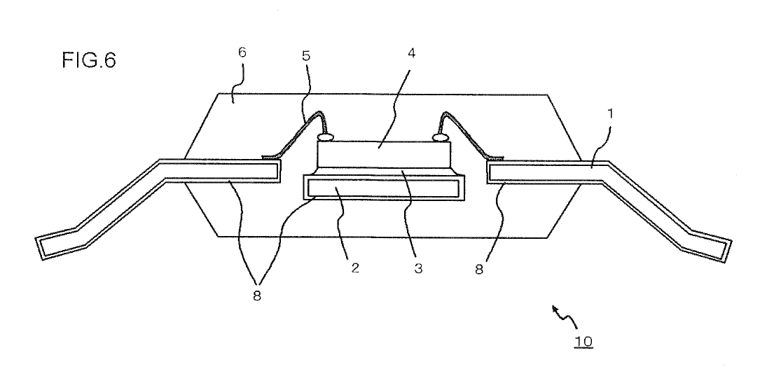

The semiconductor device of the present invention is also effectively applicable to those having minuscule-island portion on which stress is likely to concentrate during temperature cycles. FIG. 4 shows a semiconductor device 110 including a lead frame 11 having a minuscule-island portion 55, wherein area of the upper surface of the minuscule-island portion 55 is smaller than area of the lower surface of the semiconductor chip 19 opposed therewith.

Also the semiconductor device 110 may raise effects similar to those expectable from the semiconductor device 100 described in the previous embodiment.

Table 1 shows experimental results of the number of incidences of separation at the bonded portions of the inner leads, and the number of incidences of resin cracks, as compared between the semiconductor device of the present invention and the conventional semiconductor device.

TABLE 1

| | | NUMBER OF INCIDENCES OF | |
|---|---|---|---|
| | | SEPARATION AT BONDING PORTION | NUMBER OF INCIDENCES |
| | | OF INNER LEADS | OF RESIN CRACKS |
| PRODUCT | UNROUGHENED | 22/22 | 0/4 |
| WITH GENERAL ISLAND | ENTIRELY-ROUGHENED | 0/22 | 4/4 |
| | BACK SURFACE OF | 0/22 | 0/4 |
| | ISLAND UNROUGHENED | | |
| PRODUCT WITH | UNROUGHENED | 22/22 | 0/4 |
| MINUSCULE-ISLAND | ENTIRELY-ROUGHENED | 0/22 | 4/4 |
| | BACK SURFACE OF | 0/22 | 0/4 |
| | ISLAND UNROUGHENED | | |

All of 22 conventional semiconductor devices, each having a general island as shown in FIG. 1, but unroughened, were found to produce separation at the bonded portions of the inner leads. No resin crack was observed. All of entirely-roughened version of 4 semiconductor devices were found to cause resin crack. No separation at the bonding portions of the inner leads was observed. On the other hand, the semiconductor devices 100 of the present invention, each having an island portion 15 having an unroughened lower surface 15c, were found to produce neither separation at the bonding portions of the inner leads 12, nor cracks of the resin 25. The semiconductor device 110 having the minuscule-island as shown in FIG. 4 gave similar results. As is obvious from the above, the present invention can provide highly-reliable semiconductor devices.

The embodiments of the present invention have been described referring to the attached drawings, merely as examples of the present invention, allowing adoption of various configurations other than those described in the above.

For example, in the semiconductor device according to another embodiment, the lower surface 15c of the island portion 15 may include a roughened region at the center portion thereof. The roughened region is preferably formed as being equally extended inwardly from the peripheral portion of the island portion 15. If the lower surface 15c of the island portion 15 having a large surface area, unroughened over the entire surface thereof, allowed to separate from the resin 25, a gap produced between the resin 25 and the lower surface 15c of the island portion 15 may grow too large, enough to expand the semiconductor device 100.

On the contrary, according to the configuration of this embodiment, the resin 25 and the lower surface 15c of the island portion 15 can partially adhere with the aid of the roughened region at the center of the island portion 15, so that the expansion of the semiconductor device 100 may be avoidable, and the stress may be relaxed rather than being concentrated on the corners of the island, because the resin 25 is allowed to separate from the peripheral portion of the lower surface 15c of the island portion 15 left unroughened, and thereby the cracking may be prevented.

It is apparent that the present invention is not limited to the above embodiment, that may be modified and changed without departing from the scope and spirit of the invention.

What is claimed is:

1. A semiconductor device comprising:
a lead frame having an island portion having a roughened upper surface and side faces, and an unroughened lower surface, and a plurality of leads having roughened inner lead portions and unroughened outer lead portions;
a semiconductor chip placed on said upper surface of said island portion of said lead frame;
a plurality of electrode pads provided on the upper surface of said semiconductor chip;
a plurality of wires connecting said plurality of electrode pads and said plurality of leads; and
a resin molding said semiconductor chip.

2. The semiconductor device as claimed in claim 1, wherein said lead frame has a roughening plated layer formed on said upper surface and said side faces of said island portion, and on the surface of said inner lead portions of said plurality of leads.

3. The semiconductor device as claimed in claim 1,
wherein ratio of specific surface area of said roughened upper surface and said side faces of said island portion, and the roughened surface of said inner lead portions of said plurality of leads, to specific surface area of said unroughened lower surface of said island portion and said outer lead portions of said plurality of leads, is 1.15 or larger.

4. The semiconductor device as claimed in claim 1,
wherein said lead frame is a copper lead frame having a coefficient of expansion of 16 ppm or larger and 22 ppm or smaller.

5. The semiconductor device as claimed in claim 1,
wherein said lower surface of said island portion contains a roughened region at the center portion.

6. A method of manufacturing a semiconductor device comprising:
obtaining a lead frame having a plurality of leads having inner lead portions and outer lead portions, and an island portion;
masking regions other than said inner lead portions of said plurality of leads, and the upper surface and the side faces of said island portion of said lead frame;
roughening said inner lead portions of said plurality of leads, and said upper surface and said side faces of said island portion;
placing a semiconductor chip on said roughened upper surface of said island portion of said lead frame;
bonding a plurality of electrode pads provided on the upper surface of said semiconductor chip and said roughened inner lead portions of said plurality of leads; and
molding said semiconductor chip using a resin.

7. The method of manufacturing a semiconductor device as claimed in claim 6,
wherein said masking comprising masking the regions other than said upper surface, said side faces, and the center portion of the lower surface of said island portion, and said outer lead portions of said plurality of leads.
